(19) United States
(12) Patent Application Publication
(10) Pub. No.: US 2026/0110076 A1
(43) Pub. Date: Apr. 23, 2026

(54) DEPOSITION DEVICE

(71) Applicant: LG ELECTRONICS INC., Seoul (KR)

(72) Inventors: Byoungjun MOON, Seoul (KR); Jaeyoung LEE, Seoul (KR); Sunkee KIM, Seoul (KR); Changyeop JEON, Seoul (KR)

(73) Assignee: LG ELECTRONICS INC., Seoul (KR)

(21) Appl. No.: 19/121,007

(22) PCT Filed: Oct. 14, 2022
(86) PCT No.: PCT/KR2022/015543

§ 371 Date: Apr. 14, 2025

(30) Foreign Application Priority Data
Oct. 13, 2022 (KR) 10-2022-0131624

(51) Int. Cl. C23C 14/28; B23K 26/342; H10K 71/16

(52) U.S. Cl. CPC C23C 14/28; B23K 26/342; H10K 71/16

(57) ABSTRACT

A deposition device may include a chamber including a space, an evaporation source accommodated in the chamber, a laser configured to output a laser beam to the evaporation source, a main glass disposed on the chamber and configured to receive the laser beam, a cover plate accommodated in the space and including a plurality of cover glasses, and a rotation mechanism configured to rotate the cover plate so that the plurality of cover glasses selectively face the main glass. In addition, the laser may be located above the evaporation source.

### TECHNICAL FIELD

The present disclosure relates to a deposition device.

### BACKGROUND ART

Deposition is a method of depositing a thin solid film of gaseous particles on the surface of an object such as metal or glass.

Recently, as the use of OLED (Organic Light Emitting Diodes) displays has increased in electronic devices such as TVs and mobile phones, research on devices for manufacturing OLED display panels has been active. In particular, the OLED display panel manufacturing process includes a process of depositing organic materials on a glass substrate in a vacuum.

Specifically, the deposition process includes a process of heating a crucible containing an organic material to evaporate the organic material into a gaseous state, and a process of passing the gaseous organic material through a nozzle and depositing the gaseous organic material on a substrate.

However, during the deposition process, the gaseous organic material may not move to the substrate and may be deposited around the nozzle to form a film or block the nozzle hole, which may cause a clogging phenomenon.

When clogging phenomenon occurs, there is a problem that organic materials are unevenly deposited on the glass substrate, or when clogging phenomenon occurs seriously, the deposition process must be stopped to clean the nozzle.

Clogging formed in the hole of the nozzle can be removed by a laser beam output from a laser, and Korean Patent Publication No. 10-2237185 (published on Apr. 7, 2021) discloses a deposition device system including a laser that outputs a laser beam toward a nozzle of a deposition source.

The deposition device system includes a vacuum chamber, at least one viewport provided on one side of the vacuum chamber; a deposition device including a crucible accommodated inside the vacuum chamber and accommodating a deposition raw material, a heater part for heating the crucible, and at least one nozzle through which a deposition material evaporated from the deposition raw material passes; a camera positioned outside the viewport and photographing the nozzle through the viewport; a laser positioned outside the viewport and outputting a laser beam toward the nozzle through the viewport; a laser movement means for moving the laser beam output from the laser to a point of the nozzle; and a control part for receiving a nozzle image photographed by the camera and controlling the operation of the laser and the laser movement means according to a result of detecting clogging in the nozzle image.

The deposition device system includes a viewport through which a laser beam output from a laser is transmitted and on which a coating layer is formed on an outer surface, and glass positioned opposite the viewport on the lower side of the viewport and which is replaced according to the degree of contamination.

The deposition device system is such that when the glass is contaminated, the laser can heat the glass, and it is desirable for the operator to replace the contaminated glass to minimize the performance degradation of the laser.

In this case, the deposition device system can release the vacuum chamber's vacuum for replacement of the contaminated glass, and the operator can replace the glass while releasing the vacuum chamber's vacuum.

### DISCLOSURE

### Technical Problem

An object of the present embodiment is to provide a deposition device capable of minimizing the number of times a vacuum of a chamber is released and maximizing the total deposition time for depositing an object to be deposited.

### Technical Solution

A deposition device according to the present embodiment may include a chamber having a space formed in the chamber; an evaporation source accommodated in the chamber and equipped with a nozzle; a laser outputting a laser beam from above the evaporation source to the nozzle; a main glass disposed in the chamber and through which the laser beam passes; a cover plate accommodated in the space and on which a plurality of cover glasses are seated; and a rotation mechanism rotating the cover plate so that the plurality of cover glasses selectively face the main glass.

A guide groove along which the cover glass is guided may be formed on the upper surface of the cover plate. A sealing member may be disposed in the guide groove.

The rotation mechanism may comprise a shaft penetrating a through-hole formed in an upper portion of the chamber and connected to the cover plate.

The deposition device may further comprise a shield disposed on a lower side of the cover plate and having an opening formed in the shield.

The deposition device may further comprise a shutter for opening and closing a lower side of the opening.

The deposition device may further comprise a bearing disposed on the shield and rotatably supporting the shaft.

The deposition device may further comprise a fastening member accommodated in the space and coupled to a lower end of the shaft.

The rotation mechanism may further comprise a motor configured to rotate the shaft.

The deposition device may further comprise a lifting and lowering mechanism disposed in the chamber and lifting and lowering the rotation mechanism.

The lifting and lowering mechanism may comprise a base plate on which the rotation mechanism is mounted; a cylinder connected to the base plate and lifting and lowering the base plate; and a cylinder supporter mounted on an upper plate of the chamber and supporting the cylinder.

The deposition device may further comprise a hollow body disposed between the upper plate of the chamber and the base plate and surrounding the shaft. The hollow may include a bellows.

### Advantageous Effect

According to this embodiment, there is no need to release the vacuum of the chamber until all of the plurality of cover glasses are contaminated, and the total deposition time of an object to be deposited by the deposition device can be maximized.

### DESCRIPTION OF DRAWINGS

FIG. 1 is a cross-sectional view illustrating a chamber of a deposition device according to the present embodiment;

FIG. 2 is a view illustrating an evaporation source according to the present embodiment;

FIG. 3 is a view illustrating when a laser according to the present embodiment outputs a laser to a nozzle;

FIG. 4 is a perspective view illustrating a turret mechanism according to the present embodiment;

FIG. 5 is a partially cut-away perspective view illustrating a turret mechanism according to the present embodiment;

FIG. 6 is a partially cut-away perspective view illustrating an example of a shield according to the present embodiment being restrained by a chamber;

FIG. 7 is a view illustrating when a shield according to the present embodiment shields an opening in a cover plate.

### BEST MODE

Hereinafter, specific embodiments of the present disclosure will be described in detail with reference to the drawings.

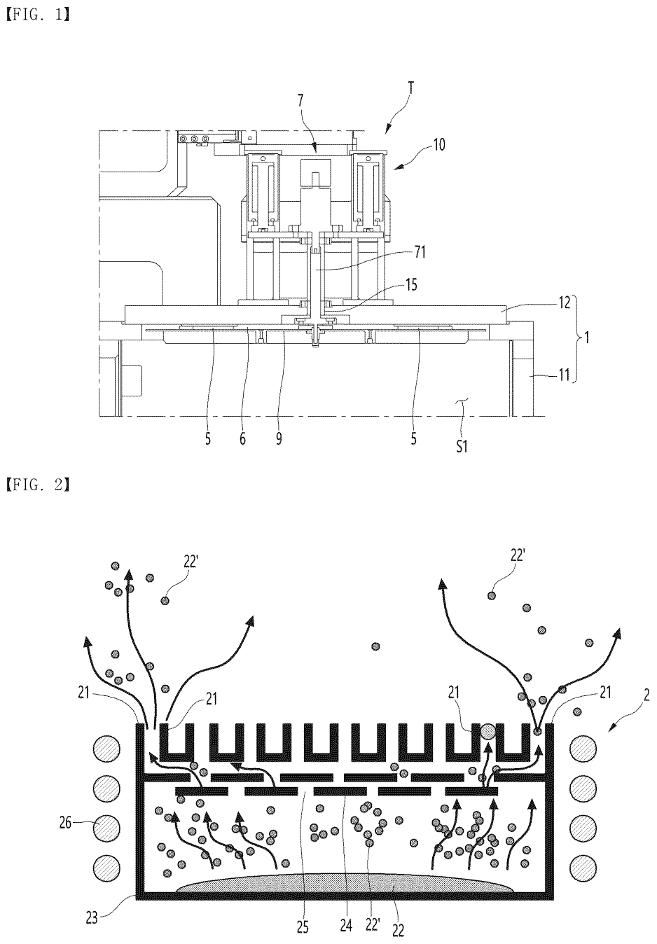

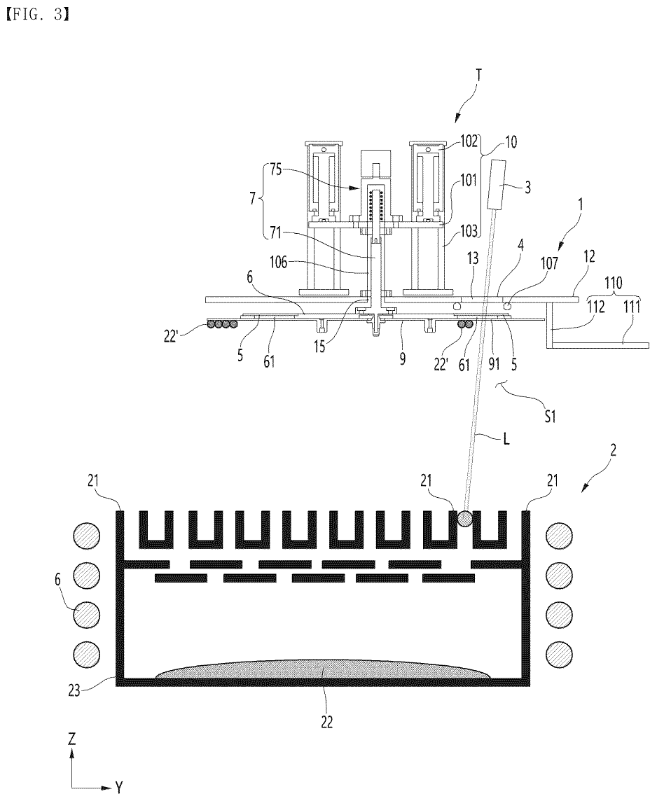

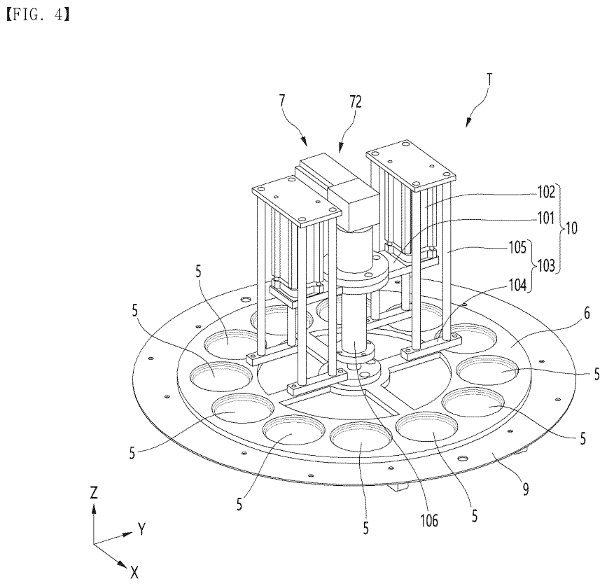

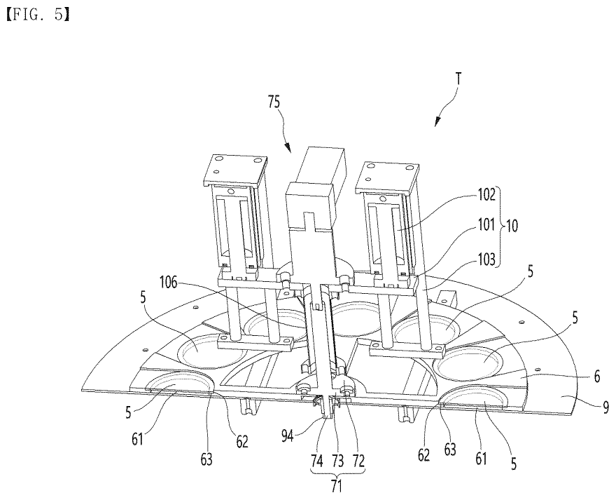

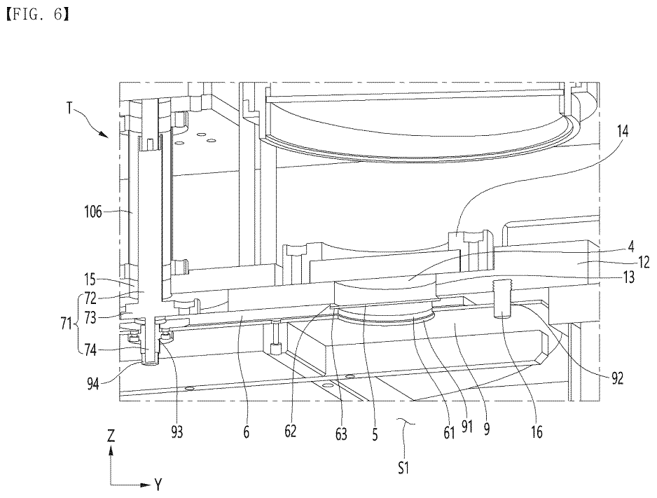

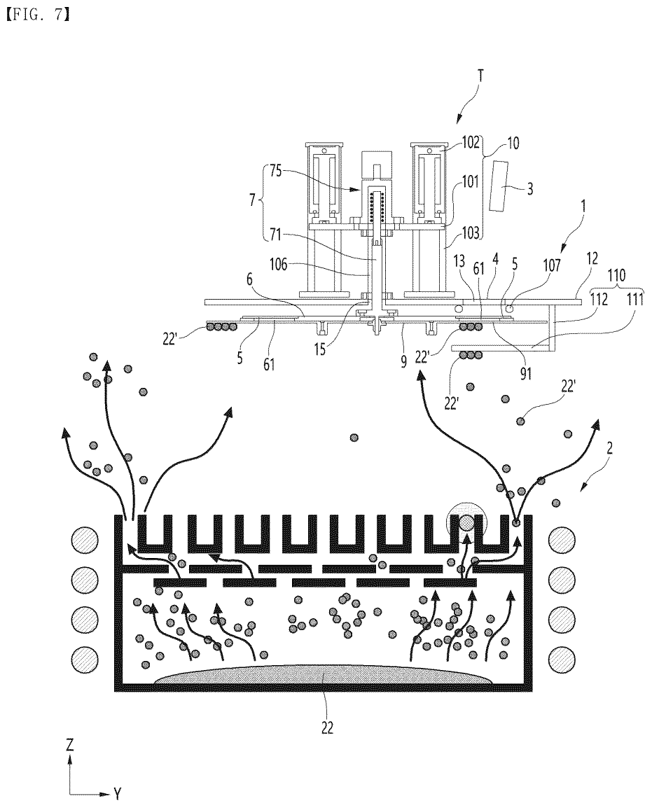

FIG. 1 is a cross-sectional view illustrating a chamber of a deposition device according to the present embodiment, FIG. 2 is a view illustrating an evaporation source according to the present embodiment, FIG. 3 is a view illustrating when a laser according to the present embodiment outputs a laser to a nozzle, FIG. 4 is a perspective view illustrating a turret mechanism according to the present embodiment, FIG. 5 is a partially cut-away perspective view illustrating a turret mechanism according to the present embodiment, and FIG. 6 is a partially cut-away perspective view illustrating an example of a shield according to the present embodiment being restrained by a chamber.

The deposition device may include a chamber 1, an evaporation source 2, a laser 3, a main glass 4, and a cover glass 5.

The chamber 1 can form the outer appearance of the deposition device. As illustrated in FIG. 1, a space S1 can be formed inside the chamber 1. An object to be deposited (hereinafter referred to as an object to be deposited) such as an OLED substrate can enter the inside of the chamber 1, and during a deposition process in which deposition particles 22′ are deposited on the object to be deposited, the chamber 1 can be a vacuum chamber in which a vacuum is maintained.

The chamber 1 may be composed of a combination of multiple members. As illustrated in FIG. 1, the deposition chamber 1 may include a chamber body 11 having a space 1 formed therein, and a top plate 12, (or an upper plate) disposed on the upper portion of the chamber body 11 and covering the space S1.

The top plate 12 can be detachably coupled to the chamber body 11.

An opening 13 (shown in FIG. 3) may be formed in at least one of the chamber body 11 and the top plate 12. A laser beam L output from a laser 3 (shown in FIG. 3) may pass through the opening 13. Hereinafter, it will be described that the opening 13 is formed in the top plate 12.

One example of a deposition device is one in which the main glass 4 (shown in FIG. 6) may be disposed on the inside of the opening 13. Another example of a deposition device is one in which the main glass 4 may be disposed on the upper side of the opening 13.

A main glass holder 14 (shown in FIG. 6) that fixes the main glass 4 to the chamber 1 can be disposed on at least one of the chamber body 11 and the top plate 12. The main glass holder 14 can be fastened to the periphery of the opening 13 using a fastening member such as a screw, and the main glass 4 can be maintained between the main glass holder 14 and the chamber 1. The chamber 1 can further include the main glass holder 14.

A member capable of maintaining airtightness, for example, a main glass sealing member (not illustrated), may be disposed between the main glass 4 and the top plate 12.

A shaft through-hole 15 (shown in FIG. 1, FIG. 3, and FIG. 6) through which a shaft 71 described later can rotatably pass through can be formed in the upper portion of the chamber 1, that is, the top plate 12.

A support pin 16 (shown in FIG. 6) that restricts the rotation of a shield 9 (shown in FIG. 6) described later may protrude downward from the upper portion of the chamber 1, that is., the top plate 12.

The support pin 16 can integrally protrude downward from the top plate 12, or can be manufactured separately from the top plate 12 and then attached/detached to/from the top plate 12 using a screw or the like.

A pin insertion part may be formed in the top plate 12 into which a support pin 16 is inserted and fixed. The pin insertion part may have a shape that is recessed upward into the bottom surface of the top plate 12. The support pin 16 may be inserted into the pin insertion part and fixed to the top plate 12.

The evaporation source 2 (shown in FIG. 2) can be accommodated in the space S1.

The evaporation source 2 may be equipped with a nozzle 21 for discharging deposition particles 22′. A plurality of nozzles 21 may be formed on the upper portion of the evaporation source 1.

The evaporation source 2 may include a crucible 23. The interior of the crucible 23 may contain a deposition material 22.

At least one inner plate 24 through which deposition particles 22′ pass may be disposed inside the evaporation source 2. At least one through-hole 25 through which deposition particles 22′ pass may be formed in the inner plate 24.

The evaporation source 2 may further include a heater 26 (shown in FIG. 2).

The heater 26 can heat the crucible 23 from the outside of the crucible 23.

A deposition material 22 inside the crucible 23 can be evaporated by heat generated and conducted from the heater 26. The deposition particles 22′ evaporated inside the crucible 22 can pass through the nozzle 21 and be discharged to the upper side of the evaporation source 2 and can be deposited on the object to be deposited located in the space S1 of the chamber 1.

The deposition particles 22′ may condense when there is a phase change due to a temperature difference, and clogging may occur in the nozzle 21 due to the phase change of the deposition particles 22′.

The laser 3 (shown in FIG. 3) can output a laser beam L from above the evaporation source 2 to the nozzle 21. The laser 3 can be disposed outside the chamber 1. The laser 3 can output a laser beam L from above the chamber 1.

The main glass 4 can be disposed inside the opening 13 of the chamber 1 or above the opening 13, and the laser beam L output from the laser 3 can transmit through the main glass 4 and the opening 13.

Hereinafter, it is explained that the main glass 4 is disposed on the upper side of the periphery of the opening 13.

An example of the main glass 4 may be a coated glass having a coating layer formed on the outer surface of the glass.

The cover glass 5 (shown in FIGS. 3 to 6) can cover the main glass 4. The cover glass 5 can protect the main glass 4.

The cover glass 5 is positioned facing the main glass 4 to minimize attachment of deposition particles 22′ to the main glass 4.

The cover glass 5 can be disposed inside the chamber 1 and accommodated in the space 1.

The cover glass 5 can face the main glass 4 in the vertical direction Z from the lower side of the main glass 4, and the deposition particles 22′ lifted from the evaporation source 2 can be attached to the lower surface of the cover glass 5, and the cover glass 5 can be contaminated instead of the main glass 4.

The cover glass 5 may be a protective glass that protects the main glass 4. The cover glass 5 may be contaminated by deposition particles 22′ and, if the contamination is excessive, may be replaced.

The deposition device may include a plurality of cover glasses 5, and when the plurality of cover glasses 5 are contaminated, the vacuum of the chamber 1 is released and at least one of the plurality of cover glasses 5 can be replaced.

When all of the plurality of cover glasses 5 are contaminated, the chamber 1 can be de-evacuated and the plurality of cover glasses 5 can be washed or replaced.

If the deposition device includes a plurality of cover glasses 5, the cycle for releasing the vacuum of the chamber 1 becomes longer, and the deposition device can minimize the vacuum releasing time of the chamber 1, so that a plurality of the object to be deposited can be deposited more quickly.

The deposition device may include a turret mechanism T (shown in FIGS. 3 to 6).

The turret mechanism T can move a plurality of cover glasses 5 so that the plurality of cover glasses 5 are selectively directed toward the main glass 4.

The turret mechanism T may include a cover plate 6 and a rotation mechanism 7.

The cover plate 6 can be accommodated in the space S1. The cover plate 6 is connected to a rotation mechanism 7 and can be rotated by the rotation mechanism 7.

A plurality of cover glasses 5 can be seated on the cover plate 6 and supported by the cover plate 6. The plurality of cover glasses 5 can be selectively directed toward the main glass 4 when the cover plate 6 is rotated by the rotation mechanism 7.

A plurality of openings 61 (shown in FIGS. 3, 5, and 6) can be formed in the cover plate 6. The number of openings 61 can be the same as the number of cover glasses 5. The laser beam L output from the laser 3 can pass through the cover glass 5 and then through the openings 61, as illustrated in FIG. 3.

A guide groove 62 (shown in FIGS. 5 and 6) along which a cover glass 5 is guided may be formed on the upper surface of the cover plate 6. The guide groove 62 may be formed by being recessed downward on the upper surface of the cover plate 6. The guide groove 62 may be formed by being recessed downward on the upper side of the periphery of the opening 61. The opening 61 may be formed to be open in the vertical direction Z at a part of the cover plate 6 where the guide groove 62 is formed.

The number of guide grooves 62 may be the same as the number of cover glasses 5. A plurality of guide grooves 62 may be spaced apart from each other in the circumferential direction of the cover plate 6.

A sealing member 63 can be disposed in the guide groove 62. The sealing member 63 can seal the deposition particles 22′ between the guide groove 62 and the cover glass 5.

Examples of sealing members 63 may include elastic materials such as Teflon seals or O-rings.

When the deposition device further includes a sealing member 63, the cover glass 5 can be seated to the sealing member 63. The sealing member 63 can prevent the cover glass 5 or cover plate 6 from being damaged by vibration or the like.

The rotation mechanism 7 (shown in FIGS. 3 to 6) can rotate the cover plate 6 so that the cover glass 5 faces the main glass 4.

The rotation mechanism 7 may include a shaft 71.

The shaft 71 can pass through the through-hole 15 formed in the upper portion of the chamber 1.

The shaft 71 is connected to the cover plate 6 and can rotate the cover plate 6.

The shaft 71 can be disposed lengthwise in the vertical direction Z.

As illustrated in FIG. 6, the shaft 71 may include a large-diameter part 72 having a connecting part formed at the upper portion, a fastening part 73 that protrudes radially from the large-diameter part 72 and is fastened to the cover plate 6, and a small-diameter part 74 formed at the lower part of the large-diameter part 72.

The fastening part 73 can be seated to the cover plate 6, and the fastening part 73 can be fastened to the cover plate 6 using a fastening member such as a screw.

A screw thread may be formed on the outer circumference of the small-diameter part 74 to be screw-connected to a fastening member 94 (shown in FIGS. 5 and 6) described later.

The rotation mechanism 7 may include a motor 75 that rotates a shaft 71. The motor 75 may be disposed outside the chamber 1. The motor 75 may rotate the shaft 71 outside the chamber 1.

The motor 75 can be connected to the shaft 71. The rotational shaft of the motor 75 can be directly connected to the connection part of the shaft 71, or can be connected to the connection part of the shaft 71 through a separate power transmission member such as a gear. When the deposition device includes a power transmission member, the deposition device may further include a sealing device such as a ferro seal.

The deposition device may further include a shield 9 (shown in FIGS. 3 to 6) that blocks the cover plate 6.

The upper surface of the shield 9 can face the lower surface of the cover plate 6 in the vertical direction Z. The shield 9 can prevent deposition particles 22′ from attaching to the cover plate 6.

An opening (Open Port) 91 can be formed in the shield 9. One opening 91 can be formed in the shield 9 and can form a path for a laser beam L.

The opening 91 can face one of the plurality of openings 61 of the cover plate 5 in the vertical direction Z. The opening 91 can face one of the plurality of cover glasses 5 in the vertical direction Z. The opening 91 can face the main glass 4 in the vertical direction Z.

As illustrated in FIG. 6, a hole 92 into which a fixed pin 16 is inserted may be formed in the shield 9. The fixed pin 16 may pass through the hole 92, and the shield 9 may be restricted from rotation by being caught on the fixed pin 16. The shield 9 may not rotate even if the base plate 101 described below rotates.

The shield 9 can support the shaft 71. The deposition device can further include a bearing 93 that is disposed on the shield 9 and rotatably supports the shaft 71. The bearing 93 can be mounted on the shield 9 by a fastening member such as a screw. The lower end of the shaft 7, that is, the small-diameter part 74, can pass through the bearing 93, and the shield 9 can rotatably support the shaft 9 in a fixed state.

The bearing 93 can guide relative motion between the shield 9 and the shaft 71. The bearing 93 can support the shield 9.

The deposition device may further include a fastening member 94. The fastening member 94 may be accommodated in the space S1 of the chamber 1. The fastening member 94 may be coupled to the lower end of the shaft 7. A male screw may be formed in the small-diameter part 74 of the shaft 7, and the fastening member 94 may be a nut that is screw-fastened to the male screw. The fastening member 94 may be a bearing stopper that may support the bearing 93 and restrict the bearing 93 from being dislodged in a downward direction.

The fastening member 94 is fastened to the shaft 71, and the shield 9 can be supported by the lower part of the shaft 71 by the fastening member 94 supporting the bearing 93.

Instead of a bearing 93, a linear bush unit can be applied, and the bearing 93 or linear bush unit can be supported on a fastening member 94, particularly a nut, which is engaged with the screw threads of the shaft 71.

Hereinafter, it is described that the shaft 71 and the fastening member 94, particularly the nut, support the bearing 93, and the bearing 93 can support the shield.

The deposition device may further include a lifting and lowering mechanism 10 (shown in FIGS. 3 to 5).

The lifting and lowering mechanism 10 is disposed in the chamber 1 and can lift and lower the rotation mechanism 7.

The lifting and lowering mechanism 10 can be mounted on the upper surface of the chamber 1.

The lifting and lowering mechanism 10 may include a base plate 101, a cylinder 102, and a cylinder supporter 103.

The base plate 101 may be a lifting and lowering plate that is lifted and lowered above the chamber 1.

A rotation mechanism 7 can be mounted on the base plate 101, and when the base plate 101 is lifted and lowered, the motor 75 can be lifted and lowered together with the base plate 101.

The motor 75 may be supported on a base plate 101, and the base plate 101 may be a motor base plate on which the motor 75 is disposed.

When the base plate 101 is lifted, the motor 75 can lift together with the shaft 71, and when the base plate 101 is lowered, the motor 75 can lower together with the shaft 71.

The cylinder 102 is connected to the base plate 101 and can lift and lower the base plate 101. The cylinder 102 can be connected to the base plate 101 from the upper side of the base plate 101.

The cylinder supporter 103 can be mounted on the top plate 12 of the chamber 1. The cylinder supporter 103 can support the cylinder 102. The cylinder supporter can support the cylinder 102 so that the cylinder 102 is spaced apart from the top plate 12 of the chamber 1 in the vertical direction Z.

The cylinder supporter 103 may include a mounter 104 and a post 105.

The mounter 104 can be fastened to the top plate 12 of the chamber 1.

The post 105 can be fastened to the mounter 104 and fastened to the cylinder 102. The post 105 can extend upwardly from the mounter 102 and support the cylinder 102.

The lifting and lowering mechanism 10 can lift the rotation mechanism 7 to seal the main glass 4 during the deposition process.

Meanwhile, if the cover glass 5 located below the main glass 4 is contaminated, the lifting and lowering mechanism 10 can lower the rotation mechanism 7, and the rotation mechanism 7 can rotate the base plate 101 so that the other cover glasses 5 around the contaminated cover glass 5 face the main glass 4.

After rotating the base plate 101 so that the cover glass 5 faces the main glass 4, the lifting and lowering mechanism 10 can lift the rotation mechanism 7 again to seal the main glass 4.

If all the cover glasses 5 are contaminated, the operator can release the vacuum in the chamber 1 and wash or replace the plurality of cover glasses 5 of the cover plate 6.

The deposition device may include a hollow body 106 (shown in FIGS. 3 to 6).

The hollow body 106 can surround the outer circumference of the shaft 71. The hollow body 106 can be disposed between the top plate 12 of the chamber 1 and the base plate 101.

An example of a hollow body 106 may be a bellows.

The upper portion of the hollow body 106 can be connected to the base plate 101, and the lower part of the hollow body 106 can be connected to the top plate 12 of the chamber 1.

The interior of the hollow body 106 can face the shaft through-hole 15 of the chamber 1 in the vertical direction Z, as illustrated in FIGS. 3 and 6.

The hollow body 106 can seal between the chamber 1 and the base plate 101.

Meanwhile, the deposition device may further include a sealing member 107 (shown in FIG. 3), such as an O-ring, disposed between the upper portion of the chamber 1, that is, the top plate 12 and the cover plate 6. The space between the top plate 12 and the cover plate 6 can be sealed by the sealing member 107.

An example of a sealing member 107 may be mounted on the lower surface of the top plate 12, and when the cover plate 6 is lifted, the cover plate 6 may come into contact with the sealing member 107, and when the cover plate 6 is lowered, the cover plate 6 may not come into contact with the sealing member 107.

Another example of a sealing member 107 may be mounted on the upper surface of the cover plate 6, and when the cover plate 6 is lifted, the sealing member 107 may come into contact with the lower surface of the top plate 12, and when the cover plate 6 is lowered, the sealing member 107 may not come into contact with the lower surface of the top plate 12.

The possibility of the main glass 4 being contaminated by deposition particles 22′ can be minimized by the sealing member 107.

The deposition device may further include a shutter 110. The shutter 110 may open and close the lower side of the opening 91.

FIG. 7 is a view illustrating when a shield according to the present embodiment shields an opening in a cover plate.

As illustrated in FIG. 7, when the laser 3 is turned off, the opening 91 of the shield 9 can be covered by the shutter 110, and the deposition particles 22′ can be minimized from being attached to the lower surface of the cover glass 5 through the opening 91 of the shield 9.

The shutter 110 may include a shutter member 111 that shields the opening 91 and a shutter shaft 112 that rotates the shutter member 111. The shutter 100 may further include a shutter driving mechanism that rotates the shutter shaft 112.

The shutter driving mechanism may include a driving source such as a motor. The shutter driving mechanism may further include at least one power transmission member such as a gear that transmits the rotational power of the driving source to the shutter shaft 112.

During the deposition process, the shutter 110 can rotate the shutter member 111 to face the opening 91 of the shield 9 in the vertical direction Z, as illustrated in FIG. 7, thereby preventing the deposition particles 22′ from being attached to the cover glass 5 through the opening 91.

In the case of the shutter 110, it can be moved to an avoidance position during the lifting/lowering operation, and the use period can be extended by preventing contamination of the cover glass 5 during a long-term standby process or the like.

The shutter 110 can be rotated so that the shutter member 111 does not face the opening 91 of the shield 9 in the vertical direction Z as illustrated in FIG. 3 during the clogging removal process of the nozzle 21, and the laser beam L output from the laser 3 can be transmitted to the nozzle 21 through the opening 91 of the shield 9.

The deposition device may further include a UV lamp, a vision system, and a controller.

The UV lamp can illuminate the evaporation source 2, particularly the nozzle 21. The UV lamp can irradiate light of UV wavelength.

The vision system can photograph the nozzle 21. The vision system can include a vision camera that photographs the nozzle 21.

The controller can control the overall operation of the UV lamp, vision system, evaporation source 2, and turret system T.

Below, the operation of the deposition device configured as above is described.

The deposition device has a UV lamp and a vision system that can observe the interior of the chamber 1.

When irradiated with UV wavelength light from a UV lamp, organic materials can fluoresce due to the UV wavelength light. The fluoresced objects can be observed by a vision system.

If, in the case of an inorganic object, light of a wavelength equal to or greater than a certain intensity is irradiated, the vision system can check whether the object is clogged or not.

If the object is clogged and is equal to or larger than a set size, the controller can initiate a clogging removal process.

During the clogging removal process, the shutter 110 can be opened in an open mode, the laser 3 can output a laser beam L, and the clogging of the nozzle 21 can be removed by the laser beam L.

The above description is merely an example of the technical idea of the present disclosure, and those skilled in the art will appreciate that various modifications and variations may be made without departing from the essential characteristics of the present disclosure.

Accordingly, the embodiments disclosed in the present disclosure are not intended to limit the technical idea of the present disclosure but to explain it, and the scope of the technical idea of the present disclosure is not limited by these embodiments.

The scope of protection of the present disclosure should be interpreted by the claims below, and all technical ideas within a scope equivalent thereto should be interpreted as being included in the scope of the rights of the present disclosure.

1. A deposition device comprising:
a chamber having a space formed in the chamber;
an evaporation source accommodated in the chamber and equipped with a nozzle;
a laser outputting a laser beam from above the evaporation source to the nozzle;
a main glass disposed in the chamber and through which the laser beam passes;
a cover plate accommodated in the space and on which a plurality of cover glasses are seated; and
a rotation mechanism rotating the cover plate so that the plurality of cover glasses selectively face the main glass,
wherein the rotation mechanism comprises a shaft penetrating a through-hole formed in an upper portion of the chamber and connected to the cover plate.

2. The deposition device of claim 1, wherein a guide groove along which a cover glass among the plurality of cover glasses is guided is formed on an upper surface of the cover plate.

3. The deposition device of claim 2, wherein a sealing member is disposed in the guide groove.

4. (canceled)

5. The deposition device of claim 1, further comprising:
a shield disposed on a lower side of the cover plate and having an opening formed in the shield.

6. The deposition device of claim 5, further comprising:
a shutter for opening and closing a lower side of the opening.

7. The deposition device of claim 5, further comprising:
a bearing disposed on the shield and rotatably supporting the shaft.

8. The deposition device of claim 5, further comprising:
a fastening member accommodated in the space and coupled to a lower end of the shaft.

9. The deposition device of claim 1, wherein the rotation mechanism further comprises a motor configured to rotate the shaft.

10. The deposition device of claim 1, further comprising:
a lifting and lowering mechanism disposed in the chamber and lifting and lowering the rotation mechanism.

11. The deposition device of claim 10, wherein the lifting and lowering mechanism comprises:
a base plate on which the rotation mechanism is mounted;
a cylinder connected to the base plate and lifting and lowering the base plate; and
a cylinder supporter mounted on an upper plate of the chamber and supporting the cylinder.

12. The deposition device of claim 11, further comprising:
a hollow body disposed between the upper plate of the chamber and the base plate and surrounding the shaft.

13. The deposition device of claim 12, wherein the hollow body comprises a bellows.
